(19) United States
(12) Patent Application Publication
(10) Pub. No.: US 2004/0037971 A1
(43) Pub. Date: Feb. 26, 2004

(54) Plasma processing apparatus and processing method

(76) Inventor: Toru Otsubo, Fujisawa (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/645,548

(22) Filed: Aug. 22, 2003

Related U.S. Application Data
(62) Division of application No. 09/842,000, filed on Apr. 26, 2001.

(30) Foreign Application Priority Data
Apr. 27, 2000 (JP) 2000-128481

(51) Int. Cl. C23C 16/505

(52) U.S. Cl. 427/571; 427/248.1

(57) ABSTRACT

A plasma processing method which supplies plasma processing gas into a plasma process chamber, sets the pressure inside the plasma process chamber to the preset value, and generates plasma by capacitatively coupled discharge, emission of electromagnetic wave by radio frequency displacement current and formation of magnetic field, thereby processing a substrate. The plasma processing controls the radiated electromagnetic wave power by the radio frequency displacement current control means forming a resonant circuit, and processing a substrate while plasma distribution is controlled during plasma processing.

### CROSS REFERENCE TO RELATED APPLICATION

This is a divisional of U.S. application Ser. No. 09/842,000, filed Apr. 26, 2001, the subject matter of which is incorporated by reference herein.

### BACKGROUND OF THE INVENTION

The present invention relates to a plasma processing apparatus, which is equipped with a plasma generation means, and to a plasma processing method; and, more particularly, the invention relates to plasma etching suited to the formation of a minute pattern in a semiconductor device and liquid crystal display device and uniform processing of a large-diameter substrate, plasma CVD suited to the formation of a thin film having a minute structure, a plasma processing apparatus for plasma polymerization, and a plasma processing method.

In a plasma processing apparatus of the type which is used to produce a semiconductor device and a liquid crystal display device, for example, using a plasma, it is a requirement that the electric characteristics of the semiconductor device not be changed by control and treatment of the radical species affecting the processing performance, the energy and directionality of ions applied to the substrate to be processed, and the uniformity in plasma processing.

Regarding the control of radical species generation, Official Gazette of Japanese Patent Laid-Open No.195379/1996 discloses a plasma processing method characterized by excellent controllability of radical species generation by generation of plasma containing both capacitatively coupled and inductively coupled characteristics.

Ion energy control and ion directionality are mentioned in the Official Gazette of Japanese Patent Laid-Open No.158629/1985, which discloses a method of electronic cyclotron resonant discharge and the application of a radio frequency bias to a substrate supporting electrode. Official Gazette of Japanese Patent Laid-Open No. 206072/1993 reveals a method of generating an inductively RF coupled discharge and application of radio frequency bias to a substrate supporting electrode. These methods have realized an improvement in the directionality of ions by generation of high density plasma at a low pressure and ion energy control by application of a radio frequency bias.

Regarding uniformity control, Official Gazette of Japanese Patent Laid-Open No.195379/1996 discloses that a plasma processing technique featuring excellent controllability of plasma density distribution is realized by generation of plasma containing both capacitatively coupled and inductively coupled characteristics.

Furthermore, regarding the control of the plasma processing uniformity, the Official Gazette of Japanese Patent Laid-Open No. 283127/1986 discloses a technique in which the electrode to which radio frequency power is applied is split into multiple pieces, and power applied to each electrode is independently controlled, thereby improving the uniformity.

Official Gazette of Japanese Patent Laid-Open No. 260596/1999 reveals a technique for controlling the plasma density distribution by controlling the electromagnetic wave emission distribution.

One of the problems in treating a semiconductor device substrate using plasma is that the electrical characteristics of the semiconductor device are changed by electrical influence during plasma processing. Official Gazette of Japanese Patent Laid-Open No. 3903/2000 discloses a technique for reducing the influence of plasma processing on the electrical characteristics.

To satisfy processing characteristics required for production of a semiconductor device and liquid crystal display device, mere ion energy control is not sufficient. Processing characteristics are greatly affected by radical species, and its general control method is to change the processing conditions, such as the plasma generating radio frequency power and pressure in the process chamber.

However, radical species control based on processing conditions is limited, and differences in processing performances cannot be covered merely by changing the processing conditions if the discharge method is different, as in the case of the electronic cyclotron resonant method, inductive RF coupled method, and the most popular parallel plate electrode method mentioned as prior art.

Thus, problems remain in that the processing performances realized by the parallel plate electrode method cannot be realized by the electronic cyclotron resonant method, inductively RF coupled method, etc.

The electronic cycrotron resonant method allows effective acceleration of electrons to be achieved by resonance. Thus, the electron energy level is high, and processing is difficult when decomposition of the process gas is reduced. In the inductively RF coupled method, plasma of locally high density is formed by electromagnetic waves radiated from the antenna, and it is diffused upward. Thus, the electron energy level at the plasma generating portion is high, and the processing is difficult when decomposition of the process gas is reduced.

In the parallel plate method, by contrast, electron are accelerated on the sheath formed on the electrode surface and interface of the plasma, and the energy level is low. Thus, this method is suited to processing under the condition where process gas decomposition is reduced.

As described above, the electron acceleration mechanism in plasma is different depending on the discharge method, and this is the reason why the differences in performances of each method cannot be covered by processing conditions.

Another problem is how to ensure uniform processing of all of the substrates. To improve productivity, the diameter of the substrate to be processed has been increased from 150 mm to 200 mm, and the diameter tends to increase to 300 mm. According to the prior art, uniformity has been achieved by changing the processing conditions or by taking such similar means.

However, a change in processing conditions is insufficient, as described above, but this is one of the important means to control the radical species. This makes it necessary to ensure a uniformity of control which ensures compatibility between processing conditions which implement optimum etching characteristics and film formation characteristics and uniformity in processing.

The techniques revealed in Official Gazette of Japanese Patent Laid-Open No.195379/1996 and Official Gazette of Japanese Patent Laid-Open No. 283127/1986 are not sufficient in connection with the mutual independence between uniformity in plasma processing and the control of radical species generation, and in connection with the compatibility between uniformity control and low pressure processing. Furthermore, the plasma density distribution control method as disclosed in the Official Gazette of Japanese Patent Laid-Open No. 260596/1999 is not sufficient in the plasma distribution control range. These are the problems of the prior art.

The electrical characteristics of semiconductor devices change when plasma is used to process these semiconductor device substrates due to electrical influence during plasma processing. This problem is caused by an uneven self-bias potential occurring to the sheath between the substrate under processing and the plasma.

To control the ion energy, radio frequency power is applied to the substrate supporting electrode. One of the major reasons for uneven self-bias potential is that radio frequency current distribution resulting from application of this radio frequency power becomes uneven on the substrate.

The self-bias potential control method disclosed in the Official Gazette of Japanese Patent Laid-Open No. 3903/2000 cannot control the self-bias potential distribution, and it is insufficient to reduce the changes in electrical characteristics.

Furthermore, higher integration of semiconductor devices and greater diameter of the substrate for production have made it necessary to develop a technique providing a better controllability than the prior art, e.g. higher selectivity with underlying material, higher performance in processed shapes, more uniform processing of large-diameter substrates, and less influence upon device characteristics.

Regarding uniformity in plasma processing, the following trend has been observed. As a result of the increased diameter of the substrates to be processed, the process gas for etching and CVD processing flows from the center of the substrate to the outer periphery, and the radical species concentration distribution and the deposition film distribution become apparent. This makes it difficult to ensure uniform processing on all surfaces of the large-diameter substrate.

To solve these problems, the factors disabling uniform distribution must be offset by other etching characteristic controlling factors. One of the controlling factors is the capability of adjusting the plasma distribution as a convex/concave distribution, independently of processing conditions, such as plasma generation power and pressure.

Radical species are generated by collision between process gas and electrons in the plasma, and it is one of the factors which greatly affect the processing characteristics, such as selectivity, processed shape and film quality in etching and CVD processing by plasma. The generated volume and type of this radical species is determined by the status of the energy of the electrons in the plasma.

Furthermore, to protect against the influence of plasma processing upon the semiconductor device, distribution of the RF current flowing through the substrate must be controlled in order to control the self-bias potential distribution.

### SUMMARY OF THE INVENTION

One object of the present invention is to realize a plasma processing apparatus and processing method which have a wide control range for the status of electron energy, independently of processing conditions and uniformity control, and which are capable of controlling radical species generation.

Another object of the present invention is to realize a plasma processing apparatus and processing method comprising a uniformity control means capable of independently controlling processing conditions, such as plasma generation power and pressure, said uniformity control means providing compatibility of plasma uniformity with radical species control, ion energy control and improved ion directionality by generation of low pressure/high density plasma.

A further object of the present invention is to realize a plasma processing apparatus and processing method comprising a means for controlling the distribution of RF current flowing through the substrate, said means providing compatibility among plasma uniformity, radical species control, ion energy control and improved ion directionality.

To achieve said objectives, the present invention has the following arrangement.

(1) A plasma processing apparatus comprises a plasma processing gas supply means, an exhaust means in a plasma process chamber, a plasma generating means, and a means to process plasma using the generated plasma; said plasma generating means being characterized by further comprising an electromagnetic wave radiating means formed by displacement current and magnetic field forming means. Said electromagnetic wave radiating means further comprises a means for controlling the radio frequency displacement current flowing between the conductors by forming from each of multiple insulated conductors the electrode of said capacitatively coupled discharge means to which RF voltage is applied.

(2) A plasma processing apparatus comprises a plasma processing gas supply means, an exhaust means in a plasma process chamber, a plasma generating means, and a means for applying RF power to control the energy of ions applied to a substrate placed on a stage, wherein the facing electrode through which RF current due to said radio frequency power flows via the plasma is composed of multiple insulated conductors, and a means is provided to vary the impedance between these conductors and ground.

(3) A plasma processing apparatus comprises a plasma processing gas supply means, an exhaust means in a plasma process chamber, a plasma generating means, and a means for applying RF power to control the energy of ions applied to the substrate placed on the stage. Said plasma processing apparatus further comprises a stage for applying said radio frequency power and a means of keeping the facing electrode separated from the ground, wherein RF current due to application of radio frequency power flows through said facing electrode via plasma.

(4) For uniformity, plasma distribution is controlled by controlling the distribution of the radiated electromagnetic wave power and controlling the radio frequency power supplied to plasma in a capacitatively coupled state from multiple conductors to the which radio frequency power is applied.

The mechanism for giving energy to the electrons in the plasma from the electric field of electromagnetic waves includes a method of direct acceleration in the electric field of electromagnetic waves by increasing the electromagnetic wave power (IPC: inductively coupled plasma). Another method included in said mechanism is to accelerate electrons by matching between the direction in which electrons are rotated by the magnetic field and the direction of the electric field of electromagnetic waves by application of a magnetic field (electron cyclotron resonance).

Energy is supplied by the former method when a magnetic field is not applied. When a magnetic field is applied, an electromagnetic wave passes through plasma more easily, and energy is supplied by the latter method.

When the magnetic field is applied, the direction of electron motion is matched with the direction of the electric field of electromagnetic waves, if the frequency at which electrons are rotated by the magnetic field are matched with the frequency of electromagnetic waves (electron cyclotron resonant conditions). Accordingly, electrons are accelerated until they collide with gas molecules, thereby creating high energy. If magnetic field conditions disagree with electron cyclotron resonant conditions, the direction of electron motion gradually disagrees with the direction of the electric field of electromagnetic waves, and acceleration and deceleration of electrons are repeated.

As the magnetic field conditions disagree with electronic cyclotron resonant conditions, the maximum energy reached by the electrons is reduced. The electron energy becomes lower than that under electronic cyclotron resonant conditions.

As described above, control of the magnetic field conditions allows free control of the electron energy. This makes it possible to control the generation volume and type of the radical species produced by decomposition of process gas.

In the event of disagreement with resonant conditions, the maximum energy reached by electrons has the following relationship. The percentage of reduction of the maximum energy of the electrons with respect to the percentage of disagreement of magnetic field conditions with the resonant conditions increases in direct proportion to the electromagnetic wave frequency. Under the conditions of 2.45 GHz, which is normally used, there is a sharp reduction of electron energy due to deviation from the electronic cyclotron conditions, and practical control is difficult. A practically controllable frequency range is from 200 MHz to 10 MHz.

Electron cyclotron resonance at a frequency of several tens of MHz to 300 MHz is disclosed in Oda, Noda, and Matsumura (Tokyo Institute of Technologies): Generation of Electron Cyclotron Resonance Plasma in the VHF Band: JJAP Vol.28, No.10, October, 1989 PP.1860-1862, and Official Gazette of Japanese Patent Laid-Open No. 318565/1994. The relationship between the state of electron energy and magnetic field strength is not described therein.

A means to emit electromagnetic waves was arranged in such a way that a displacement current was fed between insulated conductors and an electromagnetic wave is radiated by this displacement current. A resonant circuit having the same resonant frequency as the radio frequency to be applied, including the capacity formed between conductors, was formed between the conductors. Thus, resonant conditions were controlled, thereby controlling the displacement current and radiated electromagnetic wave power.

Multiple RF current conducting means are installed at the position opposite to the position where the substrate to be processed is mounted to ensure that control of the RF current ratio flowing through said multiple RF current conducting means will be possible.

When there is no magnetic field, an electromagnetic wave will hardly progress in the plasma. Under this condition without a magnetic field, conditions close to resonance conditions are setup, and the radiated electromagnetic wave power is increased, thereby ensuring energy to be supplied to electrons in the plasma from the electromagnetic waves at a position close to where the electromagnetic waves are radiated. Under these conditions, electron energy becomes partially high at a position close to where the electromagnetic waves are radiated, and decomposition of the process gas proceeds. This makes it difficult to effect control at the state of low dissociation.

Under the condition where a magnetic field is applied, electromagnetic waves are likely to progress in the plasma. This allows energy to be supplied from electromagnetic waves into the electrons in the plasma over the entire space where plasma is generated. This leads to uniform distribution of electronic energy. Furthermore, the electron energy level is also made low, and control is effected in the state of low dissociation.

As under the condition without a magnetic field, if energy is supplied at a position close to where electromagnetic waves are radiated, a high density plasma is formed in this portion, and diffusion from this position allows plasma to reach the substrate to be processed. In such a mechanism, therefore, diffusion is changed by pressure, and the plasma density and the plasma distribution on the substrate to be processed is affected by pressure.

By contrast, when a magnetic field is applied and energy is supplied over the entire space where plasma is generated, they are not affected by diffusion of the plasma. So, the plasma distribution is not easily affected by processing conditions, such as pressure. Such conditions are essential to control processing conditions and plasma distribution independently.

As a means of controlling the uniformity according to the present invention, multiple portions were provided where electromagnetic waves were radiated by a displacement current, and an arrangement was made to ensure that the amount of radiated electromagnetic waves could be controlled at least at one of said portions. The resonance conditions control method described above is used for this control. The portion radiating electromagnetic waves is provided in a double configuration to have a circular form, so that the plasma distribution can be controlled as a convex/concave distribution by controlling each radiated electromagnetic wave.

Furthermore, when the magnetic field is applied, plasma is generated over the entire plasma generation space. Then changes in the plasma distribution are less often caused by processing conditions, and plasma distribution control by control of resonance conditions can be effected independently of processing conditions. Also, the generated volume and type of the radical species can be controlled by magnetic field, independently of the uniformity control and processing conditions.

If the conductor portion radiating electromagnetic waves is provided close to the plasma, the power can be supplied to plasma by capacitative coupling. Therefore, in accordance with the present invention, discharge can be made by the same capacitative coupling as that of the parallel plate electrode method under the conditions where resonant circuit current is reduced without the magnetic field being applied. An inductively coupled discharge due to electromagnetic wave emission is caused by increasing the resonant circuit current, and a discharge under electron cyclotron resonance conditions can be caused by application of a magnetic field.

A capacitatively coupled discharge, inductively coupled discharge and electronic cyclotron discharge each have different states of electron energy and different states of process gas decomposition. The present invention allows radical species to be controlled by controlling the discharge method, in addition to radical species control by magnetic field as described above.

The energy of the ions applied to the substrate placed on the stage is controlled by application of radio frequency power. Radio frequency current by this radio frequency power is fed to the facing electrode through the plasma.

To solve the problem that electric characteristics of the semiconductor device are changed by electric influence during plasma processing, this facing electrode is composed of multiple insulated conductors, and the radio frequency current flowing through the substrate mounted on the stage is made uniform by optimization of the impedance between these conductors and ground. This has ensured a uniform distribution of self-bias potential on the substrate, and has reduced changes in the electric characteristics of the semiconductor device resulting from electric influence during plasma processing.

Also, the stage and facing electrode through which radio frequency current flows via the plasma are kept separated from the ground. This greatly reduces the percentage of radio frequency current flowing from the stage into the plasma by application of radio frequency power, with respect to that flowing to the conductor connected to the ground other than the facing electrode.

This allows almost all radio frequency currents to flow between the stage and the facing electrode. Also, the radio frequency current on the stage can be made uniform by installing the facing electrode parallel with the stage. This can reduce changes in electric characteristics of the semiconductor device resulting from electric influence during plasma processing.

### BRIEF DESCRIPTION OF THE DRAWINGS

FIG. 1 is a schematic diagram representing a plasma processing apparatus representing a first Embodiment according to the present invention;

FIG. 2 is a schematic circuit diagram representing a resonant circuit model in the first Embodiment according to the present invention;

FIG. 3 is a graph representing a plasma density distribution control in the first Embodiment according to the present invention;

FIG. 4 is a graph representing a plasma density distribution control in the first Embodiment according to the present invention;

FIG. 5 is a graph representing a plasma density distribution control in the first Embodiment according to the present invention;

FIG. 6 is a graph representing the relationship between variable capacitor capacity and plasma density distribution uniformity in the first Embodiment according to the present invention;

FIG. 7 is a diagram showing a radio frequency current path model based on application of radio frequency bias in the prior art;

FIG. 8 is a diagram representing a radio frequency current path model based on application of radio frequency bias in the first Embodiment according to the present invention;

FIG. 9 is a diagram representing the arrangement of a cover member representing a first Embodiment according to the present invention;

FIG. 10 is a schematic diagram representing a plasma processing apparatus representing a second Embodiment according to the present invention; and

FIG. 11 is a processing time diagram representing the progress of etching in the second Embodiment according to the present invention.

### DETAILED DESCRIPTION OF THE PREFERRED EMBODIMENTS

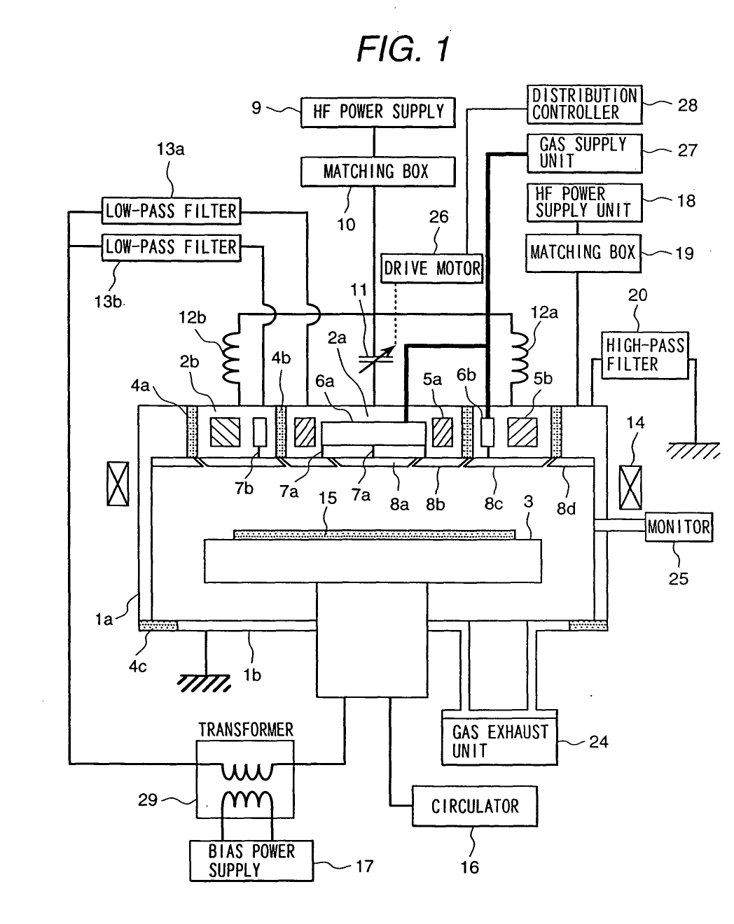

A first embodiment of the present invention will be described with reference to FIGS. 1-9 of the attached drawings. FIG. 1 is a schematic diagram of a plasma processing apparatus representing the first Embodiment.

A process chamber 1 comprises inner wall surfaces 1a and 1b, and both inner wall surfaces are insulated from each other by an insulator 4c. Facing electrode 2a, 2b and stage electrode 3 are disposed therein in face-to-face relation with each other. The inner wall surfaces 1a and 1b are insulated from the facing electrode 2b by an insulator 4a and from the stage electrode 3 by an insulator (not illustrated). The facing electrodes 2a and 2b are insulated from each other by an insulator 4b.

Connections between the inner wall surface of the process chamber 1, the electrodes and the insulators are vacuum sealed. Refrigerant flow paths 5a and 5b, and the process gas supply paths 6a and 6b are provided inside the facing electrode. Refrigerant flow paths 5a and 5b are connected to a circulator (not illustrated) to ensure that the facing electrode temperature will be kept at a set value.

Process gas supply paths 6a and 6b are connected to the process gas supply source 27 so that process gas at the set flowrate can be supplied. Covers 8a, 8b, 8c and 8d are mounted on the surface of the facing electrode, and each cover forms a space of 0.2 mm with the adjacent cover.

Process gas is supplied to the back of the covers 8a, 8b and 8c through gas inlets 7a and 7b from process gas supply paths 6a and 6b. Passing through the 0.2 mm space between covers, the gas is fed to the process chamber 1.

The inner wall surface 1a is connected with a radio frequency power supply 18 and matching box 19. It is also connected with a high pass filter 20 in conformity to the frequency of the radio frequency power supply 9, so that radio frequency current from radio frequency power supply 9 is fed to the ground.

Facing electrode 2a is connected with radio frequency power supply 9 through matching box 10 and variable capacitor 11, and facing electrode 2b is connected with radio frequency power supply 9 through matching box 10 and inductors 12a and 12b.

Facing electrodes 2a and 2b are connected with low pass filters 13a and 13b in conformity to the frequency of the bias power supply 17, so that radio frequency current from the bias power supply 17 applied to the stage electrode 3 can be fed to a transformer 29 through facing electrodes 2a and 2b.

A coil 14 is provided on the outer periphery of the process chamber 1 so that a magnetic field intersecting at right angles with the facing electrodes 2a and 2b is formed in the process chamber.

A substrate 15 can be mounted on the stage electrode 3. It is chucked on the surface of the stage electrode 3 by an electrostatic chucking unit (not illustrated), and refrigerant is supplied from a circulator 16 to a temperature controller (not illustrated) to permit control of the temperature of the substrate 15 during plasma processing.

Furthermore, a stage electrode 3 is connected with a bias power supply (2 MHz) 17 through transformer 29 in order to control the energy of the ions applied to the substrate during plasma processing. A transformer 29 is separated from the ground to reduce the capacitive component with the ground. The outer periphery of the stage electrode 3 is composed of a member connected to the ground.

The interior of the process chamber 1 is arranged to be exhausted to the state of vacuum by an exhaust controller 24 and the exhausting capacity can be adjusted and the pressure can be adjusted to the set value. A monitor 25 is installed in the process chamber 1 to monitor the progress of plasma processing.

A variable capacitor 11 has its capacity value controlled by a drive motor 26 controlled by distribution controller 28.

The following description provides an example of etching as carried out in the first Embodiment of the present invention. A substrate 10 is inserted into the plasma chamber and is placed on the stage electrode 3. Etching gas (carbon fluoride based gas) of the set flowrate is fed from an etching gas supply source 27, and the exhaust is controlled so that pressure in the process chamber will be 1 Pa.

Etching gas is supplied to the back of covers 8a and 8b from process gas supply paths 6a and 6b through gas inlets 7a and 7b. To feed gas to the process chamber 1 through the 0.2 mm space between covers, the pressure on the back of the covers is increased and the covers are cooled by facing electrodes 2a and 2b.

A silicon oxide film as an insulator of a semiconductor device and a silicon film are formed on the substrate. This substrate is electrostatically chucked on the stage electrode 3, and helium gas is supplied between the substrate and stage electrode 3 from a helium gas supply source (not illustrated), thereby reducing the thermal resistance from the substrate to the stage electrode 3 and avoiding a rise in the temperature of the substrate being etched.

From the radio frequency power supply 9, 100 MHz, 2000 W radio frequency power is applied to the facing electrodes 2a and 2b, and plasma is generated by capacitatively coupled discharge.

First, the principle of emission of electromagnetic wave from the outer periphery of the insulator 4a will be described.

When radio frequency power is supplied to the facing electrode, a radio frequency potential occurs on the facing electrode 2b. Since the inner wall surface 1a is connected to the ground through a bypass filter, radio frequency displacement current flows to the facing electrode 2b and inner wall surface 1a. This displacement current is fed through the insulator 4a, so electromagnetic waves are radiated by this radio frequency displacement current into the process chamber 1 through the space between the covers 8c and 8d.

Next, emission of electromagnetic waves from the insulator 4b on the inner periphery will be explained.

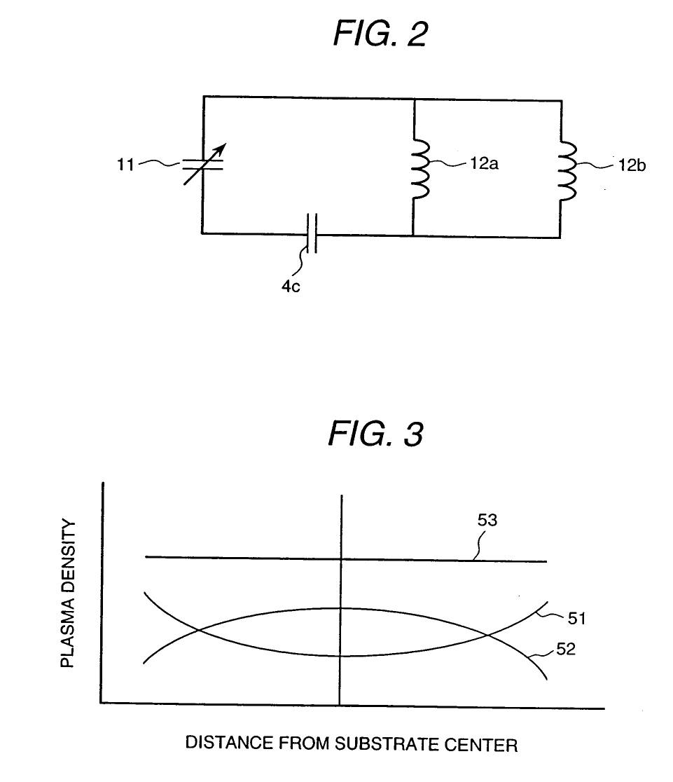

The insulator 4b between facing electrodes 2a and 2b is formulated into a model by means of a capacitor. A resonant circuit as shown in FIG. 2 is formed by this capacitor 4c, variable capacitor 11, and inductors 12a and 12b. When the capacity of the variable capacitor 11 comes close to the resonant conditions, a greater amount of radio frequency current flows to this circuit. When the capacity of the variable capacitor 11 fails to meet the resonant conditions, the radio frequency current flowing to this circuit is reduced.

As described above, displacement current flowing to the insulator 4b can control the variable capacitor 11, and electromagnetic waves are radiated in direct proportion to the radio frequency displacement current flowing to insulator 4b. Furthermore, electromagnetic waves are radiated into the process chamber 1 through the space between covers 8b and 8c. The electromagnetic wave emission power can be controlled by controlling the radio frequency displacement current flowing to the resonant circuit using the capacity of the variable capacitor 11.

The density of the plasma generated from electromagnetic waves radiated from the insulator 4a on the outer periphery exhibits a convex distribution with a high outer periphery, similar to the plasma distribution 51 shown in FIG. 3. The density of the plasma generated electromagnetic waves radiated from the insulator 4b on the inner periphery exhibits a concave distribution with a high central portion, similar to the plasma distribution 52 shown in FIG. 3.

The overall plasma distribution is obtained by superimposing the distribution of the plasma resulting from electromagnetic waves radiated from this outer periphery over that resulting from electromagnetic waves radiated from the inner periphery. A uniform plasma can be formed by adjusting the power of the electromagnetic waves radiated from the inner periphery, where the plasma density distribution in the vicinity of the substrate 15 within the range from 300 mm is within 5%, as in the case of plasma density distribution 53.

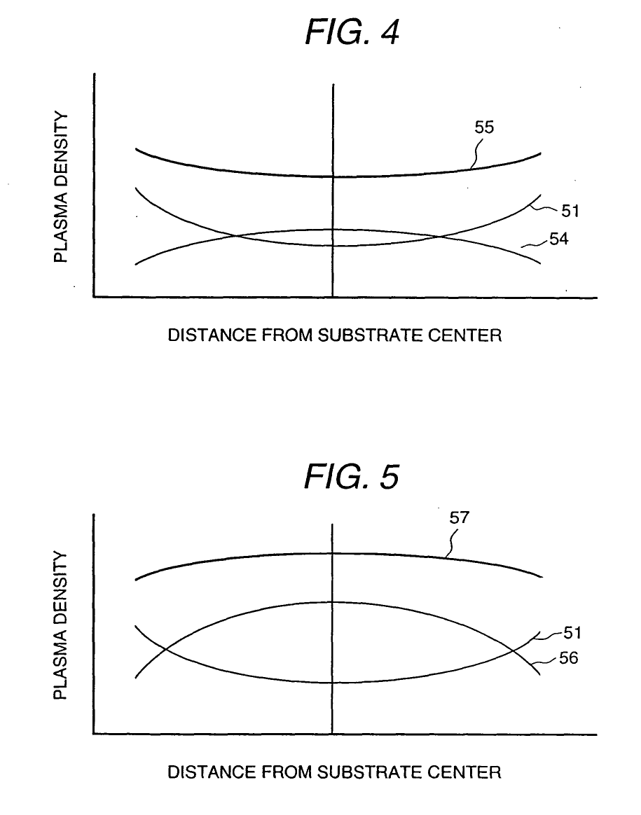

If the power of the electromagnetic waves radiated from the inner periphery is reduced, the density of the plasma generated from electromagnetic waves radiated from the inner periphery is reduced as in the case of the plasma density distribution 54 shown in FIG. 4. The overall plasma density distribution exhibits a convex distribution, as shown by the plasma density distribution 55.

If the power of the electromagnetic waves radiated from the inner periphery is increased, the density of the plasma generated from the electromagnetic waves radiated from the inner periphery is increased, as in the case of plasma density distribution 56 shown in FIG. 5. The overall plasma density distribution exhibits a concave distribution, as shown by the plasma density distribution 57.

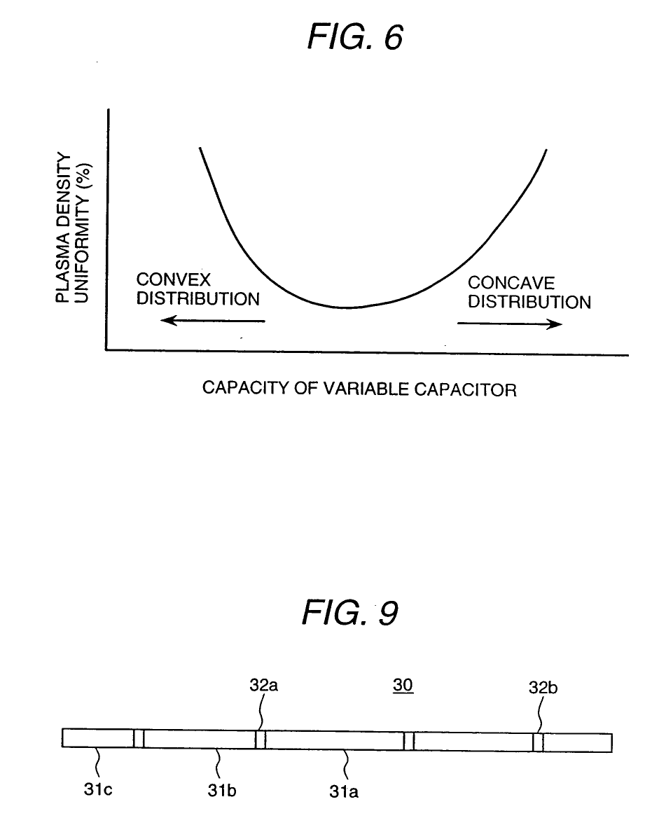

FIG. 6 shows the relationship between the capacity of the variable capacitor 11 and the uniformity of the plasma density. An increase in the capacitor capacity causes the plasma density distribution to be changed from convex to flat, then to a concave distribution, showing that the plasma density distribution can be controlled by the capacity of the variable capacitor 11.

The capacity of the variable capacitor 11 is controlled from the distribution controller 28 and drive motor 26. Such control is also possible during etching.

When a magnetic field is not formed, the electromagnetic waves are reflected by the generated plasma, and the influence on the plasma is small. In this case, the discharge is a mostly capacitatively coupled discharge, so that the electron energy distribution of the plasma is close to the Maxwell-Boltzmann distribution.

When a magnetic field is formed, current is fed to coil 14 to form the magnetic field. This magnetic field is formed almost in conformity to the direction of said electromagnetic wave emission. In the vicinity where electron cyclotron resonance (35G (35×10⁻⁴T)) is caused by the magnetic field strength with respect to the frequency of the radiated electromagnetic waves, energy is supplied to the electrons in the plasma more effectively than simply from the electromagnetic wave electric field, thereby allowing the electron energy to be increased.

At 100 MHz electron cyclotron resonance, as in the case of the first Embodiment of the present invention, the rotating angular velocity of the electrons is reduced in direct proportion to the electromagnetic wave frequency, compared with the electron cyclotron resonance due to a conventional 2.45 GHz microwave. However, the electric field of the electromagnetic wave accelerating electrons remains unchanged if the power density is the same, without depending on frequency. The same energy can be given to the electrons.

If the frequency is low, the angular velocity is reduced, so that a disagreement between the cyclotron frequency due to the magnetic field and the frequency of the electromagnetic waves occurs. This increases tolerance in exchange for energy. In the case of 100 MHz, for example, electrons can be accelerated to the level required for ionization and generation of radical species in a wide range of magnetic field strength from 10G (10×10⁻⁴T) to 70G (70×10⁻⁴T).

In this case, the maximum energy of the electrons to be accelerated is reduced with increasing departure from electronic cyclotron conditions, making it possible to control the state of electron energy according to the magnetic field strength. Namely, the electron energy can be changed from a level suited to generation of the radical species up to the level of ionization by changing the magnetic field strength.

In the first Embodiment according to the present invention, the magnetic field strength is set to 50G (50×10⁻⁴T), which is higher than the electronic cyclotron condition. The condition is set to the state where the maximum electron energy is reduced.

Such an effect is measured because the electromagnetic wave frequency is within the range from 200 MHz to 10 MHz. Easy use and excellent effects can be ensured especially within the range from 100 MHz to 50 MHz. If the electromagnetic wave frequency is 200 MHz, the range where there is an effect of controlling the state of electron energy by the magnetic field strength is reduced in inverse proportion to the frequency, so that this range is up to about 100G (100×10⁻⁴T). In the case of 10 MHz, the effect of the magnetic field can be measured when the magnetic field strength is about 2G (2×10⁻⁴T) or more.

When 2 MHz radio frequency power of 1000W is supplied to a stage electrode 3 from the bias power supply 17, the voltage of 700 Vpp appears, and ions from the plasma are accelerated by this voltage. It is applied to the substrate 15. Etching gas (carbon fluoride based gas) decomposed by the plasma with the aid of ions reacts with the silicon oxide film and silicon film on the back of the substrate 15, and etching takes place.

If the electron energy level is high, decomposition of carbon fluoride based gas takes place and the fluorine based radical species increases in number, resulting in an improved etching rate of silicon film. In an advanced state of gas decomposition, the cross section geometry of the etching shows an almost vertical shape. If decomposition does not proceed, a forward tapered shape tends to be produced.

In the production of a semiconductor device the etching rate of the silicon film with respect to that of the silicon oxide film as an insulator must be minimized, and the cross section geometry of etching must be made as close as possible to a vertical shape. This requires an adequate control of the decomposition of the carbon fluoride based gas. It is also necessary to find a condition which ensures compatibility between the two.

When electromagnetic waves are not radiated (magnetic field: OT), decomposition of the etching gas does not proceed, and etching is performed to produce a forward tapered shape. If the magnetic field strength is increased, gas decomposition proceeds and a nearly vertical shape is formed. At the same time, as the etching rate increases, so the etching velocity ratio increases conversely. It drops suddenly when a condition to promote further decomposition is established.

As described above, decomposition of this carbon fluoride based gas can be controlled by changing the magnetic field, according to the present invention. The present invention makes it possible to optimize etching characteristics, such as the etching velocity ratio between a silicon oxide film and a silicon film, and the etching shape.

Furthermore, optimization of the etching characteristics can be controlled by the magnetic field, independently of process conditions, such as pressure, etching gas flowrate and radio frequency power. This allows process conditions to be determined by fine processing, processing velocity and such related factors, resulting in an expanded margin of processing.

Radio frequency power is applied to the stage electrode 3 from the bias power supply 17 through transformer 29. Radio frequency current passes through the substrate 15 and the plasma, and flows to facing electrodes 2a and 2b. Since the transformer 29 is separated from or is floated with respect to the ground, almost all the radio frequency current flowing from the stage electrode 3 is fed to facing electrodes 2a and 2b, without going to any other places.

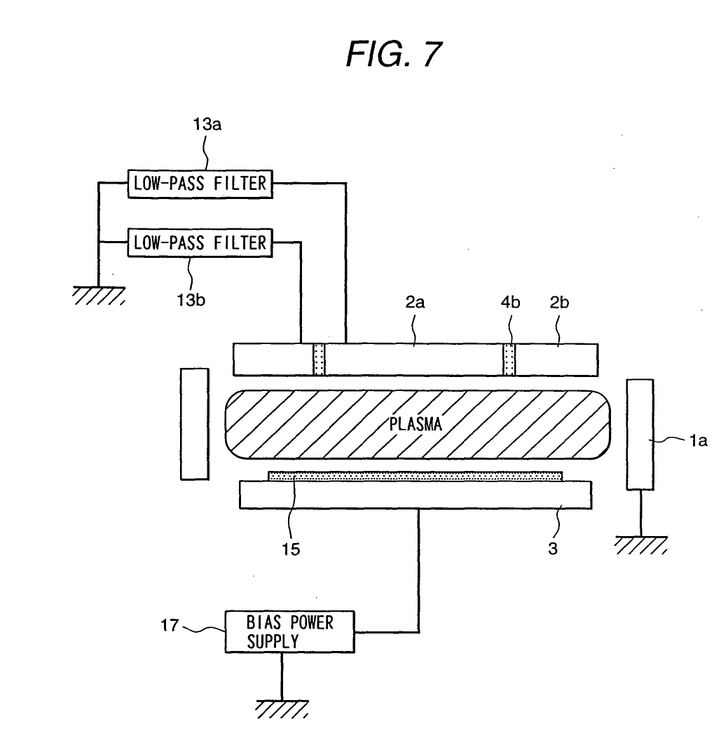

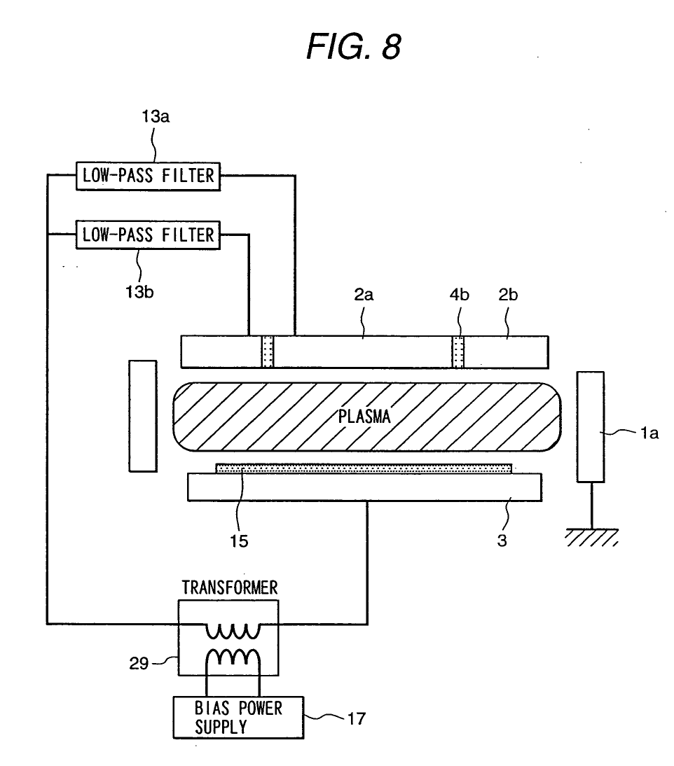

The radio frequency bias current path controlling the energy of ions applied to this substrate 15 is formulated into a model and is shown in FIG. 7 as a normal path. FIG. 8 shows the path of this Embodiment. The difference between the two will be discussed below.

In the normal arrangement, one of the outputs from bias power source 17 connected to the stage electrode 3 is connected to the ground, as shown in FIG. 7. The radio frequency voltage output terminal is connected to the stage electrode 3. Passing through substrate 15, radio frequency current is fed to the facing electrodes 2a and 2b and to the inner wall 1a of the process chamber through the plasma. Passing through the ground, it goes back to the bias power supply 17.

On the outer periphery of stage electrode 3, radio frequency current can flow to both the facing electrode 2b and inner wall 1a of the process chamber. Thus, the current path impedance is reduced to facilitate the flow of radio frequency current, and the density of the radio frequency current flowing through the substrate 15 exhibits a distribution which is high on the outer periphery and low at the central portion. This is one of the biggest causes for changes in the characteristics when the semiconductor device substrate is processed.

In this Embodiment, as shown in FIG. 8, the output of the bias power supply 17 is separated from or is floated with respect to the ground and is connected through the transformer 29 to the stage electrode 3. A current circuit is provided in such a way that the current can return to the transformer from facing electrodes 2a and 2b through low pass filters 13a and 13b.

If an arrangement is made to reduce the capacitative component between the current circuit for the current to return to the transformer and ground, the current flows from the stage electrode 3 to the inner wall 1a of the process chamber, and the impedance of the path for the current to return to the transformer is increased. Thus, radio frequency current flowing through this path is greatly reduced. Therefore, the radio frequency current flowing from the stage electrode 3 mostly flows to the facing electrodes 2a and 2b.

As a result, parallel installation of the stage electrode 3 and the facing electrodes 2a and 2b makes the radio frequency current distribution almost uniform. This leads to a substantial relief of the problem that electric characteristics of the semiconductor device are much changed by electrical influence during plasma processing.

The impedance of the bias power supply 17 to frequency can be made variable by shifting the characteristics of the low pass filters 13a and 13b with respect to the frequency of bias power supply 17.

If the low pass filter 13a is set so that the impedance is minimized and the impedance of low pass filter 13b is set to a value higher than that, the radio frequency current passing through the substrate 15 will exhibit a distribution where the current density is high at the central portion and is low on the outer periphery. If setting of the low pass filter impedance is reversed, the distribution will show that the current density is high on the outer periphery and low at the central portion.

As described above, the optimization of the impedance of the low pass filters 13a and 13b allows for more uniform control of the self-bias potential distribution occurring at the substrate 15, and further reduces the changes in the electric characteristics of the semiconductor device due to plasma processing.

Furthermore, if the low pass filters 13a and 13b are controlled by the drive motor and distribution control similar to the variable capacitor 11, then control can be effected to reach the optimum state where changes in the electric characteristics of the semiconductor device do not occur with respect to changes in processing conditions and changes in the state during processing.

When etching is continued, a deposition film is formed on the inner wall surface of the process chamber 1. This film will eventually become separated, thereby to produce dust. Since ions from the plasma are applied to the facing electrodes 2a and 2b at an increased velocity by the radio frequency power to be applied, a deposition film does not stick to the surface of the electrode, and so no dust is produced. When 400 kHz radio frequency power is supplied from the radio frequency power supply 18 to the inner wall surface 1a, radio frequency current flows to the inner wall surface 1b connected to the ground through the plasma and the outer periphery of the stage electrode 3. A deposition film can be prevented from attaching onto the inner wall surface by accelerating entering the inner wall.

Covers 8a to 8d are made of silicon, and the effect differs according to the silicon resistance. The case of using silicon having a high resistance has been mentioned in the Embodiment discussed above.

When low-resistance silicon is used, a displacement current flowing between the facing electrodes 2a and 2b does not flow through the insulator 4b due to the limited space of 0.2 mm between each of the covers 8a to 8d. It flows mainly between covers 8b and 8c. Radio frequency displacement current flowing between the facing electrode 2b and process chamber 1a flows mainly between covers 8c and 8d.

When the space between covers is set so as to be inclined with respect to the magnetic field, displacement current flows in the direction at a right angle to the inclined surface, and electromagnetic waves are radiated in the inclined direction of the space, as shown in the Figure.

A sheath is formed between the cover and the plasma when plasma is generated, and electromagnetic waves radiated in an inclined direction with respect to the magnetic field are divided into two components, a component which proceeds along the magnetic field in the plasma, and a component which travels through the sheath.

The electromagnetic wave traveling through the sheath proceed gradually in the direction of the magnetic field, so that the electromagnetic waves exhibit a flat distribution as compared to the case where electromagnetic waves are radiated in a direction parallel with the magnetic field. If this property is utilized, a uniform plasma can be formed even when the electromagnetic wave radiating portion is arranged in a single ring electrode structure. However, this does not allow electric control of the plasma distribution.

Even when the electromagnetic wave radiating portion is provided in the form of a double ring electrode arrangement, there is an effect of improving the distribution controllability, because a flat distribution is ensured for both the plasma generated by electromagnetic waves from the electromagnetic wave radiating portion on the inner periphery and the plasma generated by electromagnetic waves from the electromagnetic wave radiating portion on the outer periphery.

Furthermore, although covers 8a to 8d are split parts in the present Embodiment, it should not be understood that the present invention is limited only to that configuration. FIG. 9 shows the structure of covers in accordance with another Embodiment. This cover 30 has quartz rings 32a and 32b embedded between silicon rings 31a to 31c. The cover 30 can be handled as one disk, and this improves the workability of replacement or the like.

The following describes the case of plasma CVD. Organic silane based gas, including fluorine, and oxygen gas are mixed and supplied as the process gas. The process gas is decomposed by the plasma in the process chamber to form a silicon oxide film on the substrate. Silicon oxide film adheres not only on the substrate 15, but also on covers 8a to 8d on the surface of the facing electrode, as well as on the inner wall surface 1a, etc. As described above, however, ions are applied to the covers 8a to 8d on the surface of the facing electrode and inner wall surface 1a at an accelerated rate by application of radio frequency power. Accordingly, the silicon oxide film is removed by the effect of these ions and fluorine radicals generated from the fluorine contained in organic silane gas.

As described above, the first Embodiment of the present invention provides a plasma processing apparatus and a processing method characterized by a wide range of control of the electron energy state and by the capability of controlling the generation of radical species, independently of the processing conditions and the uniformity of control.

It also provides a plasma processing apparatus and processing method comprising a uniformity control means ensuring compatibility of plasma uniformity with radical species control, ion energy control and improved ion directionality by generation of low pressure high density plasma, said means being characterized by a control capability independently of such processing conditions as plasma generation power and pressure.

It also provides a plasma processing apparatus and processing method comprising a means to reduce changes of electric characteristics of the semiconductor device due to electrical influence during plasma processing, said means being capable of ensuring compatibility reduction of changes of electric characteristics of the semiconductor device due to electrical influence during plasma processing with plasma uniformity control, radical species control, ion energy control and improved ion directionality due to generation of low pressure high density plasma; and, said means is characterized by a control capability independently of such processing conditions as plasma generation power and pressure.

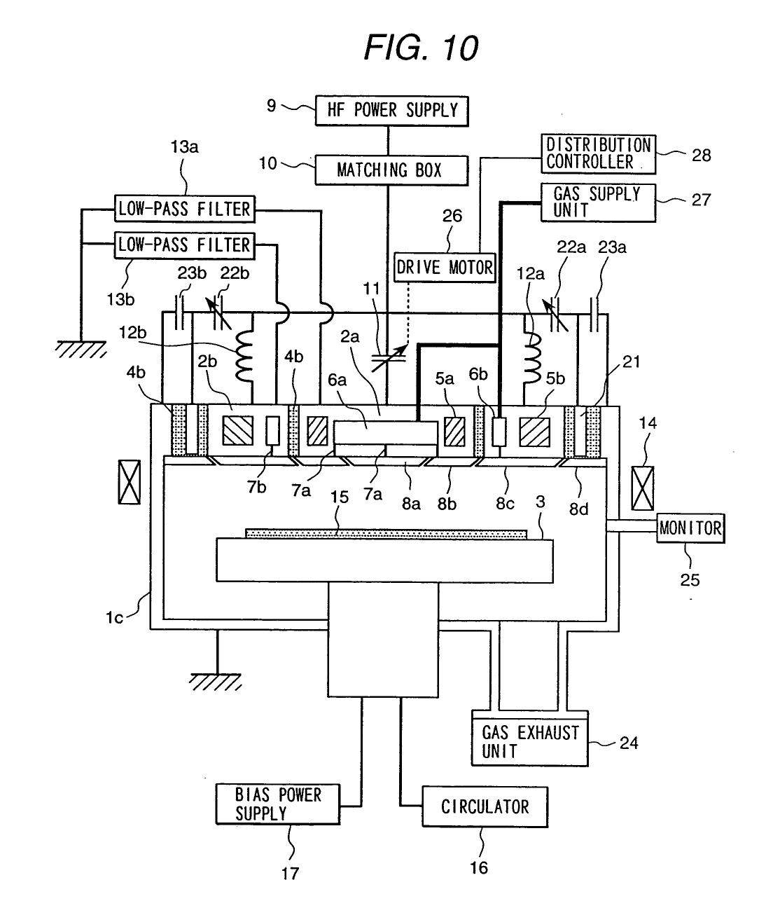

FIG. 10 is a schematic diagram representing a plasma processing apparatus as a second Embodiment according to the present invention.

The second Embodiment will be described mainly with regard to the differences from said first Embodiment, with the description of overlapping features being omitted.

The differences between the second Embodiment and the first Embodiment is that a ring block 21 is provided on the outer periphery of facing electrodes 2a and 2b. The ring block 21 is isolated from the insulator 4d, facing electrode 2b, process chamber 1c and cover 8d.

Inductors 12a and 12b and ring block 21 are connected with each other through variable capacitors 22a and 22b, and ring block 21 and process chamber 1c are connected with each other through capacitors 23a and 23b.

The following describes the process treatment carried out in the second Embodiment. Emission and control of electromagnetic waves from insulator 4b are the same as those described with reference to the first Embodiment. The resonance state of the resonant circuit composed of inductors 12a and variable capacitor 22a and the resonant circuit composed of inductor 12b and variable capacitor 22b is controlled by variable capacitors 22a and 22b, thereby controlling radio frequency displacement current between the facing electrode 2b and the ring block 21 and distribution in the circumferential direction. Thus, electromagnetic waves from between the ring block 21 and facing electrode 2b are radiated in proportion to this radio frequency displacement current.

The second Embodiment provides an optimum plasma distribution since it enables both independent control of the emission of electromagnetic waves on the inner and outer peripheries of process chamber 1c, and control of distribution in the circumferential direction.

In FIGS. 3 to 5 described above, plasma distribution is controlled by density distribution 52, 54 and 56 of the plasma generated by electromagnetic waves radiated from the central portion. In the present Embodiment, the density distribution 51 of the plasma generated by electromagnetic waves radiated from the outer periphery can also be controlled. In addition, control distribution under axially symmetric conditions and in the circumferential direction can be controlled.

An example of wired film etching in accordance with the second Embodiment will be described. Substrate 15, where an aluminum film is formed on the silicon oxide film, is installed on the stage electrode 3. After that, chlorine based etching gas is supplied into the process chamber 1c, and the pressure is set to 1 Pa. Then, radio frequency power of 1000W is supplied to the facing electrodes 2a and 2b to generate a plasma. Radio frequency power of 100W is applied to the stage electrode 3, and ions applied to the substrate 15 from the plasma are accelerated by this radio frequency bias.

On the surface of the substrate 15, a resist mask used for patterning is decomposed by the plasma, and a deposition film is formed from the decomposed gas or the like. The deposition film is removed by application of the ions, and the exposed aluminum film reacts with a chlorine based radical species generated in the plasma, thereby ensuring progress of the etching.

The deposition film formed on the surface of the substrate 15 is not formed uniformly. There is a greater volume deposited at the central portion. So the volume of ions at the center must be increased to ensure uniform etching.

When aluminum etching has been completed and the underlying silicon oxide film is exposed, etching of the silicon oxide film proceeds in proportion to the volume of ions. Under the same etching conditions as those of the aluminum film, a greater amount of silicon oxide film at the central portion will be etched. Therefore, during etching of the aluminum film and the silicon oxide film as an underlying film, the plasma distribution must be subjected to adequate in-process control according to each condition.

In this second Embodiment, variable capacitors 11, 22a and 22b are designed so as to be variable by means of a drive motor 26, distribution controller 28, or a similar drive mechanism and control mechanism. This allows plasma distribution to be controlled by the plasma processing apparatus control mechanism, similar to such processing conditions as pressure and power.

Some processing conditions are set in the controller in the etching system. Processing pressure, radio frequency power to be applied, type and volume of etching gas supplied into the process chamber and the like are memorized under one set of setting conditions. Etching is carried out by a combination of some of these setting conditions. This combination is also memorized in the controller. The etching system starts processing when the setup conditions and combination (normally called a recipe) are specified.

In accordance with the present invention, a control program is designed to allow plasma uniformity as well as pressure and power to be incorporated into this setup condition, to ensure that variable capacitor capacity can be controlled by this specification.

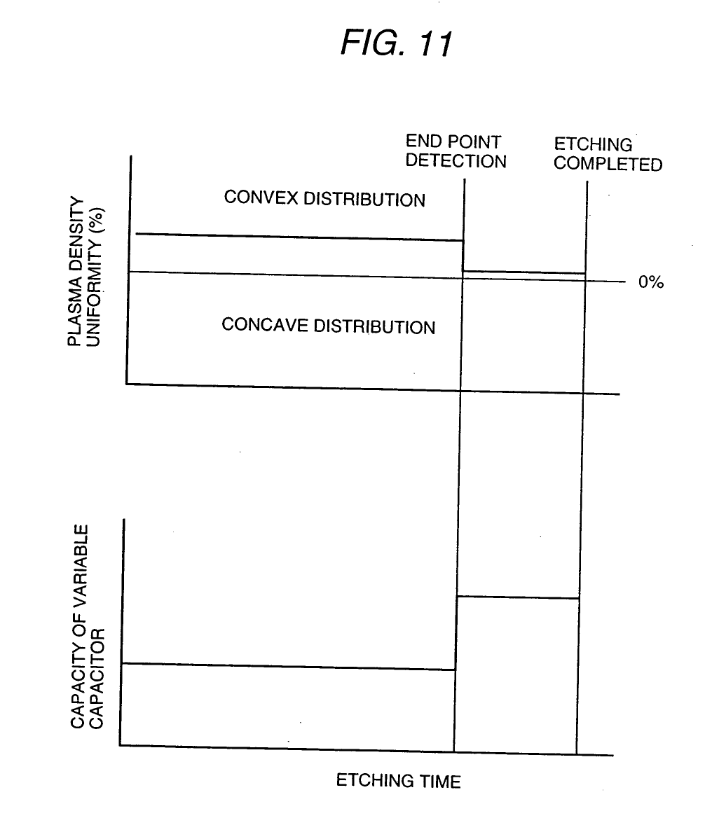

The processing procedures for etching with plasma uniformity incorporated in this condition will be described with reference to an example of the aluminum film etching described above. FIG. 11 shows the relationship between plasma uniformity control and the elapse of time in this etching procedure.

The plasma distribution is controlled by detecting the point where aluminum film etching is changed to silicon oxide film etching, where the detection is made according to the result of monitoring the end point of etching with the monitor 25.

During etching of the aluminum film, the plasma density is set to a convex distribution. Control is carried out as follows. When the end point of etching is detected by the monitor 25, the capacity of the variable capacitor 11 is increased by the drive motor, thereby obtaining a uniform plasma distribution. This state is maintained until the end of etching.

The aluminum film is not formed uniformly; the film thickness has a distribution. To form fine patterns with high precision, it is necessary to provide high precision control of over-etching time or the like after completion of etching. Etching of the aluminum film must terminate simultaneously on all surfaces of the substrate 15.

In the Embodiment according to the present invention, the thickness of the etched film is measured by a film thickness measuring means (not illustrated), and the plasma distribution is controlled for each substrate by counting backward from the result of measuring the film thickness distribution, to ensure that etching is terminated simultaneously on all surfaces of the substrate.

In this control, from the data on the etched film input into the etching controller, a calculation is made to obtain the etching rate and distribution which ensure that etching of the etched film will be terminated simultaneously on all surfaces of the substrate. Then, the plasma density distribution required for the desired etching rate is prepared. From the relationship between the capacitor capacity shown in FIG. 6 and the plasma distribution, the capacity of variable capacitors 11, 22a and 22b is calculated, and the plasma distribution is controlled by the distribution controller 28 and drive motor 26, thereby allowing etching to be carried out.

From the view point of electronic energy control, the second Embodiment has been described mainly with regard to discharge based plasma processing where the state of the electron energy is controlled under capacitatively coupled discharge conditions, where a magnetic field is not applied, to electronic cyclotron resonant conditions, where a magnetic field is applied. Plasma distribution and gas decomposition can also be controlled by discharge where a magnetic field is not used.

In the second Embodiment illustrated in FIG. 10, electromagnetic wave power applied to the central portion of the process chamber 1c is increased by increasing the displacement current flowing to the resonant circuit formed by variable capacitor 11 and inductors 12a and 12b. Then, electromagnetic wave power is supplied to the plasma as in the case of an inductively coupled plasma. However, there is much reflection from the plasma, and a greater amount of radio frequency displacement current must be supplied than in the case where a magnetic field is used.

Electromagnetic wave power radiated from the outer periphery can be controlled in the same way as that radiated from the central portion, as described above, by increasing the displacement current flowing to the resonant circuit formed by variable capacitors 22a and 22b and inductors 12a and 12b. This allows a double ring plasma on the central portion and outer periphery to be formed in the process chamber 1c by inductive coupling. Uniform plasma can be formed on the large-diameter substrate 15. Furthermore, a plasma distribution ranging from a convex distribution to a concave distribution can be controlled by controlling each of the displacement current at the central portion and the radio frequency displacement current on the outer periphery.

When this magnetic field is not used, energy is supplied intensively to the plasma in the vicinity where electromagnetic waves are radiated. Thus, the electronic energy is increased to a high level to facilitate decomposition of the process gas.

Thus, the following conditions can be controlled by the magnetic field formed by variable capacitors 11, 22a and 22b and coil 14 as provided in the present Embodiment: (1) a condition where radio frequency displacement current is reduced, and discharge is mostly carried out under the capacitatively coupled condition, (2) a condition where radio frequency displacement current is increased and a locally powerful plasma is formed to promote decomposition of the process gas, and (3) a condition where the travel of electromagnetic waves in the plasma is facilitated by formation of a magnetic field, and slow decomposition of the process gas provided by supply of energy from electromagnetic wave to plasma occurs in the entire process chamber.

The second Embodiment provides a plasma processing apparatus and processing method characterized by a wide range of control of the state of electron energy as in the case of the first Embodiment, and by the capability of controlling the generation of radical species, independently of processing conditions and uniformity control.

In the Embodiment according to the present invention, as described above, mainly etching and plasma CVD have been described. However, it should not be understood that the present invention is limited only to such processes. It is clear that the present, invention is generally applicable to processes using plasma, such as plasma polymerization and sputtering.

In the above-mentioned Embodiment according to the present invention, the frequency of the radio frequency power supply for plasma generation has been described for the case where the frequency is 100 MHz. As described in the first Embodiment, a similar effect can be obtained within the range from 200 MHz to 10 MHz.

It is also possible to store in the memory means a processing procedure for the control of the above-mentioned plasma processing distribution, and to control plasma distribution by means of a control means according to the stored processing procedure, thereby performing plasma processing.

The present invention allows the state of electron energy to be controlled independently in the plasma processing apparatus. This makes it possible to control generation of radical species, and to ensures compatibility of the characteristics, for example, between etching of high selectivity and high precision, high-speed etching, or film quality and film formation speed, where the compatibility of such characteristics has been difficult to attain in the prior art.

Furthermore, plasma density distribution can be controlled without changing the hardware configuration, and minute-pattern high-precision etching and uniform film formation are possible on all surfaces of a large-diameter substrate.

The plasma distribution can also be controlled during plasma processing, independently of process conditions. Higher precision etching and more uniform film formation can be ensured by controlling plasma distribution in conformity to the progress of plasma processing.

In accordance with the present invention, an electromagnetic wave is radiated by the control of radio frequency displacement current. According to this method, the space for radiating the electromagnetic wave can be made as narrow as about 0.2 mm, as described in the Embodiment. This method is the same as the inductively RF coupled method in that electromagnetic waves are radiated, but the space for radiating the electromagnetic waves cannot be reduced to the same extent as obtained according to the inductively RF coupled method. Thus, the present invention has the effect of allowing more stable processing than prior art methods, without being affected by a deposition film attached on the wave radiating portion.

The present invention further reduces the occurrence of changes of electric characteristics in semiconductor devices by plasma processing, and provides an effect of improving yields in semiconductor device production.

This has ensured a high performance in processing of semiconductor devices and liquid crystal display devices, and provides the effect of permitting higher performance production of devices. Namely, the present invention realizes a plasma processing apparatus and processing method which allows independent optimization of each of processing conditions, uniformity control, radical species generation control and prevention of changes in electrical characteristics.

The present invention provides the effect of using wide ranging processing conditions, without processing conditions, such as pressure and power, being restricted by the need for uniformity or prevention of changes in electrical characteristics.

What is claimed is:

1. A plasma processing method which supplies plasma processing gas into a plasma process chamber, sets the pressure inside said plasma process chamber to the preset value, and generates plasma by capacitatively coupled discharge, emission of electromagnetic wave by radio frequency displacement current and formation of magnetic field, thereby processing a substrate;
said plasma processing method comprises steps of:
controlling radiated electromagnetic wave power by the radio frequency displacement current control means forming a resonant circuit, and
processing a substrate while plasma distribution is controlled during plasma processing.

2. A plasma processing method according to claim 1, further characterized in that plasma distribution is controlled to ensure that plasma processing of said substrate is completed uniformly for every plasma processing or during plasma processing according to uneven conditions of the substrate to be processed.

3. A plasma processing method which supplies plasma processing gas into a plasma process chamber, sets the pressure inside said plasma process chamber to the preset value, and generates plasma by capacitatively coupled discharge, emission of electromagnetic wave by radio frequency displacement current and formation of magnetic field, thereby processing a substrate;
said plasma processing method comprises steps of:
setting displacement current frequency within the range from 10 MHz to 200 MHz,
controlling radiated electromagnetic wave power by the radio frequency displacement current control means forming the resonant circuit,
controlling plasma distribution during plasma processing, and
processing a substrate at the magnetic field strength within the range from 2×10⁻⁴T to 10⁻²T.

4. A plasma processing method according to claim 3, further characterized in that plasma distribution is controlled to ensure that plasma processing of said substrate is completed uniformly for every plasma processing or during plasma processing according to uneven conditions of the substrate to be processed.
